(19) United States
(12) Patent Application Publication
(10) Pub. No.: US 2022/0157911 A1
(43) Pub. Date: May 19, 2022

(54) ORGANIC SEMICONDUCTOR DEVICE

(71) Applicant: Au Optronics Corporation, Hsinchu (TW)

(72) Inventors: Shuo-Yang Sun, Hsinchu (TW); Shih-Hua Hsu, Hsinchu (TW); Ching-Wen Chen, Hsinchu (TW); Ying-Hui Lai, Hsinchu (TW)

(73) Assignee: Au Optronics Corporation, Hsinchu (TW)

(21) Appl. No.: 17/364,877

(22) Filed: Jun. 30, 2021

(30) Foreign Application Priority Data
Nov. 17, 2020 (TW) 109140031

(51) Int. Cl. H01L 27/32; H01L 51/05

(52) U.S. Cl. CPC H01L 27/3274; H01L 27/3258; H01L 51/0541; H01L 27/3276

(57) ABSTRACT

A semiconductor device is disposed and includes a substrate, on which a scan line, a data line, a source electrode, a drain electrode, an organic semiconductor pattern, an organic insulating layer, a gate electrode, and an organic protection layer are disposed. The source electrode is electrically connected to the data line. The organic semiconductor pattern is disposed between the source electrode and the drain electrode. The organic insulating layer is disposed on an upper surface and a side surface of the organic semiconductor pattern. The organic insulating layer is at least disposed between the side surface of the organic semiconductor pattern and the gate electrode and disposed between the upper surface of the organic semiconductor pattern and the gate electrode. The gate electrode is electrically connected to the scan line. The organic protection layer covers the gate electrode.

### CROSS-REFERENCE TO RELATED APPLICATION

This application claims the priority benefit of Taiwan application serial no. 109140031, filed on Nov. 17, 2020. The entirety of the above-mentioned patent application is hereby incorporated by reference herein and made a part of this specification.

### BACKGROUND

### Technology Field

The disclosure relates to a semiconductor device, and more particularly, to an organic semiconductor device.

### Description of Related Art

Organic thin-film transistors (OTFT) have advantages and characteristics such as lightness, flexibility, and low process temperature, so they have been widely used in display devices, such as liquid crystal displays, organic light emitting displays, and electrophoretic displays. However, the organic semiconductor layer in an organic thin-film transistor is easily affected by moisture, resulting in a decrease in the yield of the organic thin-film transistor. Therefore, how to prevent the organic semiconductor layer from moisture to improve the yield of the organic thin film transistor is an important issue that needs to be solved.

### SUMMARY

The disclosure provides an organic semiconductor device, capable of reducing the influence of moisture on an organic semiconductor layer.

An embodiment of the disclosure provides an organic semiconductor device. The organic semiconductor device includes a substrate; a scan line disposed on the substrate; a data line disposed on the substrate; a source electrode and a drain electrode disposed on the substrate, where the source electrode is electrically connected to the data line; an organic semiconductor pattern disposed on the substrate and between the source electrode and the drain electrode; an organic insulating layer disposed on the substrate and on an upper surface and a side surface of the organic semiconductor pattern; a gate electrode disposed on the substrate, where the organic insulating layer is disposed at least between the side surface of the organic semiconductor pattern and the gate electrode and between the upper surface of the organic semiconductor pattern and the gate electrode, and the gate electrode is electrically connected to the scan line; and an organic protection layer disposed on the substrate and covering the gate electrode.

In an embodiment of the disclosure, the organic semiconductor pattern surrounds the source electrode and the drain electrode.

In an embodiment of the disclosure, the organic insulating layer includes an island-shaped portion and a planarization portion, an annular space is sandwiched between the island-shaped portion and the planarization portion, and the annular space surrounds the island-shaped portion.

In an embodiment of the disclosure, the gate electrode is filled in the annular space.

In an embodiment of the disclosure, the organic insulating layer includes an island-shaped portion, and the gate electrode covers the island-shaped portion.

In an embodiment of the disclosure, the organic protection layer is filled between the planarization portion and the gate electrode.

In an embodiment of the disclosure, the organic semiconductor device further includes a protection pattern, and the protection pattern is disposed on the upper surface of the organic semiconductor pattern and sandwiched between the organic semiconductor pattern and the organic insulating layer.

In an embodiment of the disclosure, the organic semiconductor device further includes a planarization layer, the planarization layer is disposed between the source electrode and the drain electrode and the substrate, and at least one of the scan line and the data line is disposed between the planarization layer and the substrate.

In an embodiment of the disclosure, the organic semiconductor device further includes a conductive connection pattern, and the source electrode is connected to the data line through the conductive connection pattern.

In an embodiment of the disclosure, the source electrode is connected to the conductive connection pattern through the opening of the planarization layer.

In an embodiment of the disclosure, the organic semiconductor further includes a conductive connection pattern, and the gate electrode is connected to the scan line through the conductive connection pattern.

In an embodiment of the disclosure, the gate electrode is connected to the conductive connection pattern through an opening of the planarization layer.

In an embodiment of the disclosure, the organic semiconductor device further includes a buffer layer, and the buffer layer is disposed between the scan line and the data line and the substrate.

In an embodiment of the disclosure, the organic semiconductor device further includes a pixel electrode, and the pixel electrode is disposed on an upper surface of the organic protection layer and electrically connected to the drain electrode.

Based on the above, the organic semiconductor device of the disclosure blocks moisture through the gate electrodes disposed on the upper surface and the side surface of the organic semiconductor pattern, so as to protect the organic semiconductor pattern. Moreover, the organic material/inorganic material stack of the organic protection layer and the gate electrode also contributes to blocking moisture and preventing the properties of the organic semiconductor pattern from being affected by moisture.

In order to make the features and advantages of the disclosure comprehensible, embodiments accompanied with drawings are described in detail below.

### BRIEF DESCRIPTION OF THE DRAWINGS

FIG. 1A is a schematic top view of an organic semiconductor device according to an embodiment of the disclosure.

FIG. 1B is a schematic cross-sectional view taken along the line A-A′ of FIG. 1B.

FIG. 2A to FIG. 9A are schematic top views of the method of manufacturing the organic semiconductor device shown in FIG. 1A.

FIG. 2B to FIG. 9B are schematic cross-sectional views taken along the line A-A′ of FIG. 2A to FIG. 9A, respectively.

FIG. 10A to FIG. 13A are schematic top views of a method of manufacturing an organic semiconductor device according to an embodiment of the disclosure.

FIG. 10B to FIG. 13B are schematic cross-sectional views taken along the line A-A′ of FIG. 10A to FIG. 13A, respectively.

FIG. 14 is a schematic cross-sectional view of an organic semiconductor device according to an embodiment of the disclosure.

### DESCRIPTION OF THE EMBODIMENTS

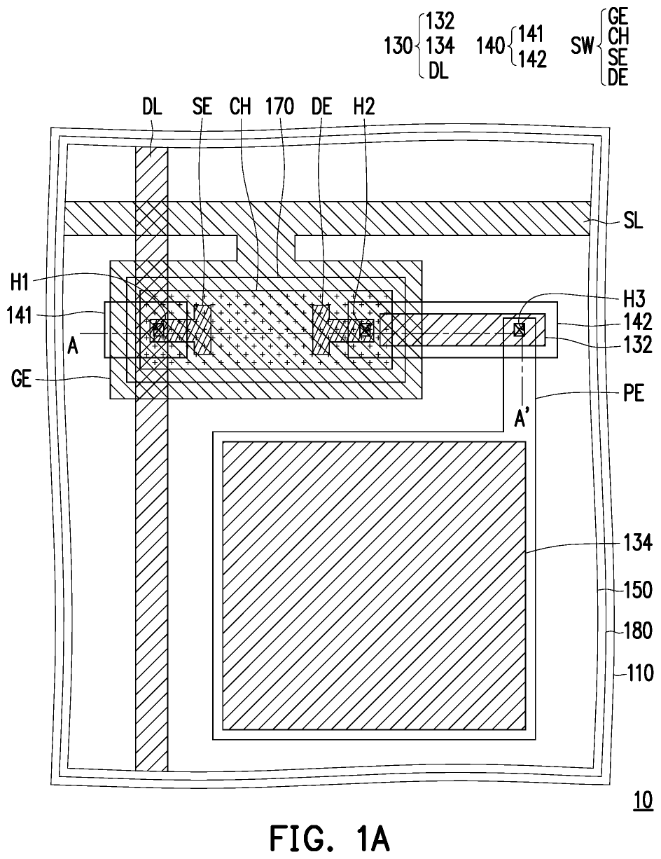

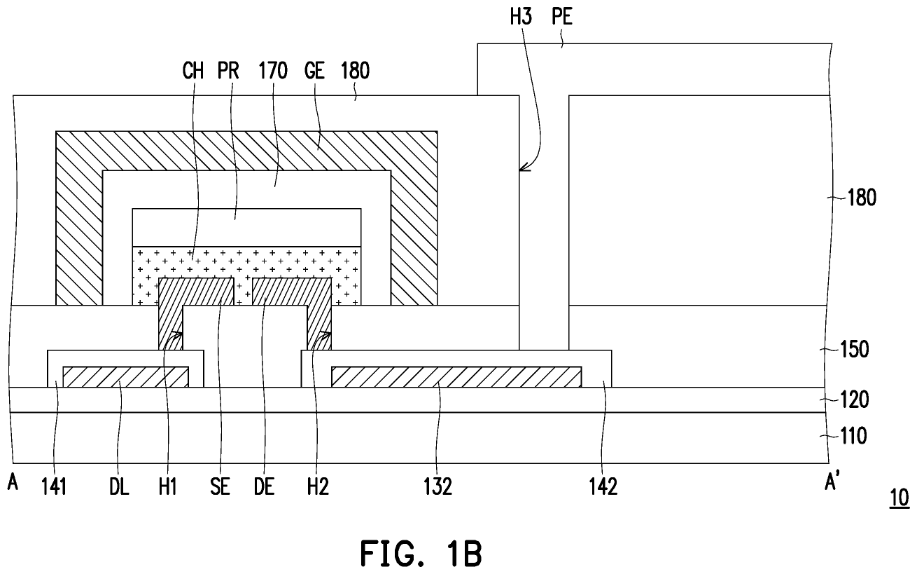

FIG. 1A is a schematic top view of an organic semiconductor device 10 according to an embodiment of the disclosure. FIG. 1B is a schematic cross-sectional view taken along the line A-A′ of FIG. 1B. The organic semiconductor device of the disclosure may be any device including a switching element, such as a display device, a touch device, a sensing device, a light emitting device, and the like. Hereinafter, refer to FIG. 1A to FIG. 1B altogether to clearly understand the overall structure of the organic semiconductor device 10.

Referring to FIG. 1A to FIG. 1B, the organic semiconductor device 10 includes a substrate 110; and a scan line SL, a data line DL, a source electrode SE, a drain electrode DE, an organic semiconductor pattern CH, an organic insulating layer 170, a gate electrode GE, and an organic protection layer 180 disposed on the substrate 110. The source electrode SE is connected to the data line DL. The organic semiconductor pattern CH is disposed between the source electrode SE and the drain electrode DE. The organic insulating layer 170 is disposed on an upper surface and a side surface of the organic semiconductor pattern CH. The organic insulating layer 170 is disposed at least between a side surface of the organic semiconductor pattern CH and the gate electrode GE and between the upper surface of the organic semiconductor pattern CH and the gate electrode GE. The gate electrode GE is connected to the scan line SL. The organic protection layer 180 covers the gate electrode GE.

Accordingly, in the organic semiconductor device 10 according to an embodiment of the disclosure, with the gate electrode GE disposed on the upper surface and the side surface of the organic semiconductor pattern CH the influence of moisture on the organic semiconductor pattern CH may be reduced, which can improve the yield of the organic semiconductor device 10.

In the subsequent paragraphs, with reference to FIG. 1A to FIG. 1B, the implementation of each element and film layer of the organic semiconductor device 10 is illustrated, but the disclosure is not limited thereto.

The substrate 110 includes a metal substrate, a glass substrate, or a flexible substrate. When the substrate 100 is a flexible substrate, its materials include flexible materials (e.g., polyamide (PA), polyimide (PI), poly (methyl methacrylate) (PMMA), polyethylene naphthalate (PEN), polyethylene terephthalate (PET), glass fiber reinforced plastics (FRP), polyetheretherketone (PEEK), epoxy resin, other suitable materials, or a combination of at least two thereof, but the disclosure is not limited thereto. Various layers for forming signal lines, switching elements, driving elements, storage capacitors, and the like can be disposed on the substrate 110.

In some embodiments, the organic semiconductor device 10 further includes a buffer layer 120 disposed between the scan line SL and the data line DL and the substrate 110. The buffer layer 120 may serve as a moisture and gas blocking layer to further reduce the influence of moisture on the organic semiconductor pattern CH.

In some embodiments, the organic semiconductor device 10 further includes a first conductive layer 130. The first conductive layer 130 can serve as an electrode, or the first conductive layer 130 can form a wire for signal transmission or electrical connection. For example, in the embodiment, the first conductive layer 130 includes the data line DL, a transfer wire 132, and a capacitor electrode 134. The data line DL is electrically connected to the source electrode SE and used to transmit the signal from the driving element to the source electrode SE. The transfer wire 132 is electrically connected to the drain electrode DE and used to transmit the signal from the drain electrode DE to the pixel electrode, for example. The capacitor electrode 134 can be used as an electrode of a storage capacitor, for example.

In some embodiments, the organic semiconductor device 10 further includes a conductive connection layer 140 that covers at least a portion of the first conductive layer 130 to protect the first conductive layer 130 from the etchant during the etching process. In some embodiments, the conductive connection layer 140 may cover a portion of the first conductive layer 130. In some embodiments, the conductive connection layer 140 may completely cover the first conductive layer 130. For example, in the embodiment, the conductive connection layer 140 includes a first conductive connection pattern 141 and a second conductive connection pattern 142, the first conductive connection pattern 141 covers part of the data line DL, and the second conductive connection pattern 142 completely covers the transfer wire 132.

In some embodiments, the organic semiconductor device 10 further includes a planarization layer 150, and the planarization layer 150 may cover the buffer layer 120, the first conductive layer 130, and the conductive connection layer 140. In some embodiments, the planarization layer 150 is disposed between the substrate 110 and the source electrode SE and the drain electrode DE, and the data line DL is disposed between the planarization layer 150 and the substrate 110. In some embodiments, the planarization layer 150 has a first opening H1 and a second opening H2, the orthographic projection of the first opening H1 on the substrate 110 overlaps the first conductive connection pattern 141, and the orthographic projection of the second opening H2 on the substrate 110 overlaps the second conductive connection pattern 142.

In the embodiment, the source electrode SE, the drain electrode DE, the organic semiconductor pattern CH, and the gate electrode GE together constitute a switching element SW. The switching element SW can be turned on or off by the signal transmitted by the scan line SL, and when the switching element SW is turned on, the signal transmitted on the data line DL can be transmitted to the drain electrode DE.

The source electrode SE and the drain electrode DE are separated from each other; the source electrode SE and the drain electrode DE may belong to the same or different conductive film layers; and the source electrode SE and the drain electrode DE may have a single-layer or multi-layer structure. In the embodiment, the source electrode SE is disposed in the first opening H1, and the drain electrode DE is disposed in the second opening H2. Therefore, the source electrode SE can be connected to the first conductive connection pattern 141 to be electrically connected to the data line DL; and the drain electrode DE can be connected to the second conductive connection pattern 142 to electrically connect to the transfer wire 132. In the embodiment, the source electrode SE and the data line DL belong to different film layers, but the disclosure is not limited thereto.

The organic semiconductor pattern CH is connected to the source electrode SE and the drain electrode DE, respectively. In some embodiments, the organic semiconductor pattern CH is disposed between the source electrode SE and the drain electrode DE. In some embodiments, the organic semiconductor pattern CH covers the source electrode SE and the drain electrode DE. In some embodiments, the organic semiconductor pattern CH surrounds the source electrode SE and the drain electrode DE to increase the conduction area between the organic semiconductor pattern CH and the source electrode SE, and the conduction area between the organic semiconductor pattern CH and the drain electrode DE, thereby improving the efficacy of the switching element SW.

The organic insulating layer 170 is disposed on the upper surface and the side surface of the organic semiconductor pattern CH. In some embodiments, the organic insulating layer 170 covers the organic semiconductor pattern CH. In some embodiments, the organic semiconductor device 10 further includes a protection pattern PR disposed between the organic insulating layer 170 and the organic semiconductor pattern CH and can serve as an etching protection layer of the organic semiconductor pattern CH.

The organic insulating layer 170 is disposed at least between the side surface of the organic semiconductor pattern CH and the gate electrode GE and between the upper surface of the organic semiconductor pattern CH and the gate electrode GE. Accordingly, the organic insulating layer 170 can prevent a short circuit between the gate electrode GE and the organic semiconductor pattern CH. The gate electrode GE and the scan line SL may belong to the same or different conductive film layers, and the gate electrode GE and the scan line SL may have a single-layer or multi-layer structure. In the embodiment, the gate electrode GE and the scan line SL belong to the same film layer. In some embodiments, the gate electrode GE is coated with the organic insulating layer 170, so moisture can be prevented from entering the switching element SW, and the performance of the switching element SW can be prevented from being affected by the moisture.

The organic protection layer 180 is disposed on the substrate 110, and the organic protection layer 180 is disposed on the upper surface and the side surface of the gate electrode GE to cover the gate electrode GE. In some embodiments, the organic protection layer 180 covers the gate electrode GE, and the organic material/inorganic material stack of the organic protection layer 180 and the gate electrode GE have a feature to further block moisture and prevent moisture from affecting the organic semiconductor pattern CH.

In some embodiments, the organic protection layer 180 has a third opening H3. The third opening H3 penetrates the organic protection layer 180 and the planarization layer 150 and exposes the second conductive connection pattern 142. In some embodiments, the organic semiconductor device 10 further includes a pixel electrode PE, and the pixel electrode PE is disposed on the upper surface of the organic protection layer 180 and in the third opening H3. The pixel electrode PE may be electrically connected to the drain electrode DE through the second conductive connection pattern 142 and the transfer wire 132. In some embodiments, the pixel electrode PE and the capacitor electrode 134 together constitute the storage capacitor of the organic semiconductor device 10.

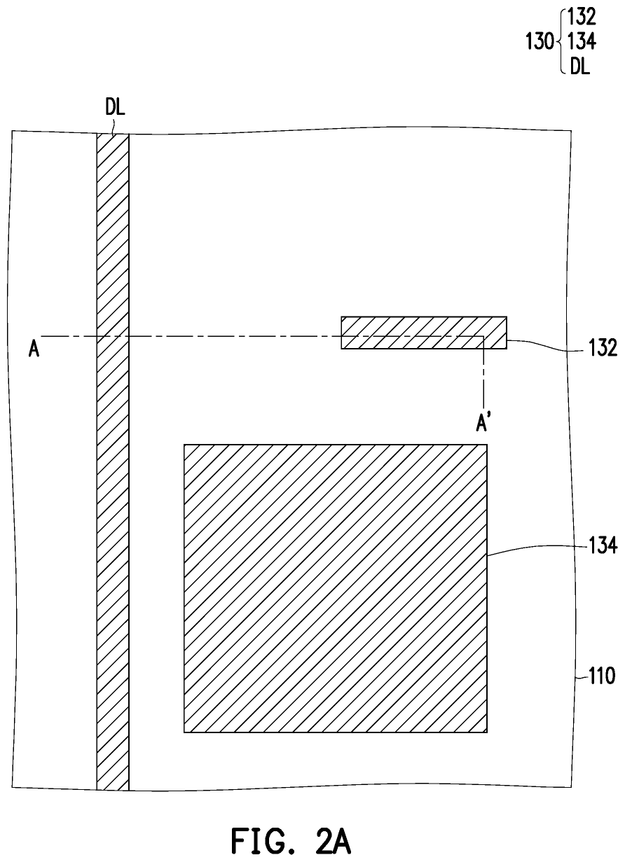

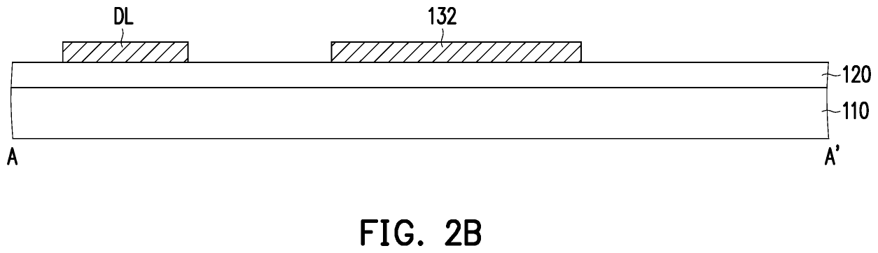

FIG. 2A to FIG. 9A are schematic top views of a method of manufacturing the organic semiconductor device 10 shown in FIG. 1A. FIG. 2B to FIG. 9B are schematic cross-sectional views taken along the line A-A′ of FIG. 2A to FIG. 9A, respectively. In the subsequent paragraphs, with reference to FIG. 2A to FIG. 9A and FIG. 2B to FIG. 9B, the implementation of each element and film layer of the organic semiconductor device 10 is illustrated, but the disclosure is not limited thereto.

Referring to FIG. 2A and FIG. 2B, the buffer layer 120 is formed on the substrate 110. The buffer layer 120 is a single-layer or multi-layer structure, for example, and its material includes silicon oxide, silicon nitride, silicon oxynitride, other suitable materials. or a combination of two or more materials thereof.

Next, the first conductive layer 130 is formed on the buffer layer 120. The first conductive layer 130 includes the data line DL, the transfer wire 132, and the capacitor electrode 134. The first conductive layer 130 may be a single-layer or a multi-layer structure. Based on the conductivity, the first conductive layer 130 generally includes metal materials, such as gold, silver, copper, aluminum, titanium, molybdenum, or a combination thereof, but the disclosure is not limited thereto. In other embodiments, the first conductive layer 130 may include an alloy, a nitride of a metal material, an oxide of a metal material, an oxynitride of a metal material, other suitable materials, or a stacked layer of the foregoing conductive materials.

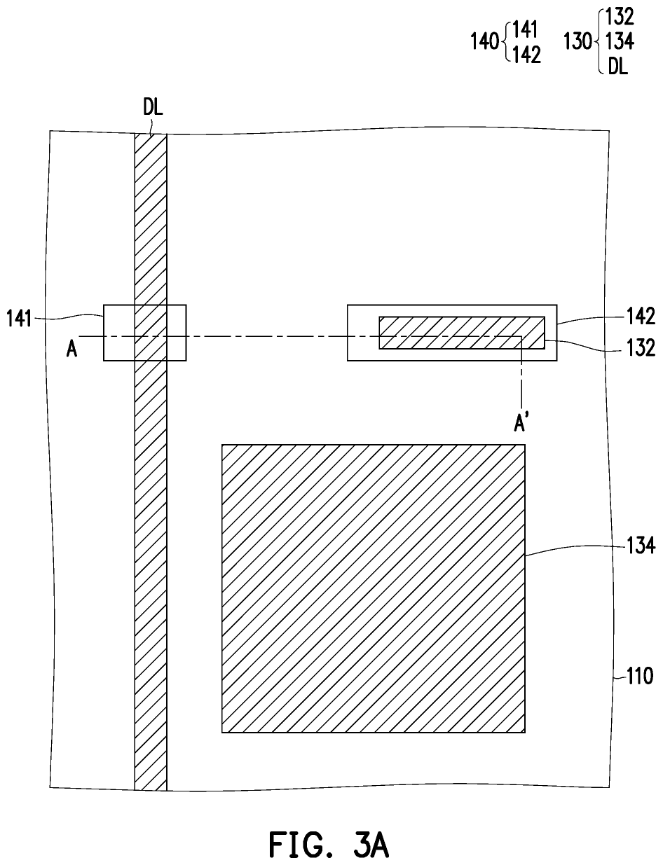

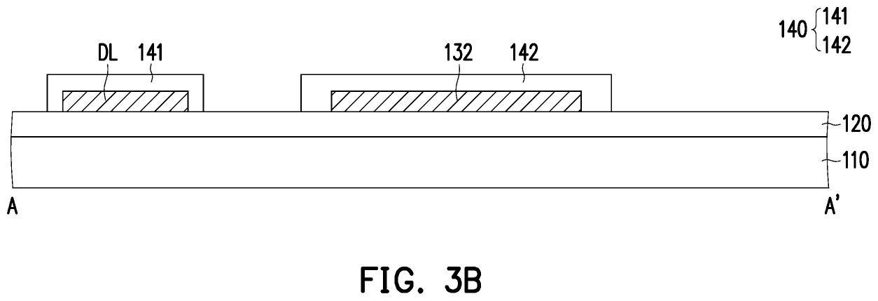

Referring to FIG. 3A and FIG. 3B, the conductive connection layer 140 is formed on the substrate 110. The conductive connection layer 140 includes a first conductive connection pattern 141 and a second conductive connection pattern 142, the first conductive connection pattern 141 covers part of the data line DL, and the second conductive connection pattern 142 completely covers the transfer wire 132. The material of the conductive connection layer 140 may include, for example, an anti-oxidation material, such as a metal (e.g., at least one of titanium, molybdenum, tungsten, gold, platinum, chromium, nickel, palladium, and cobalt, a composite layer thereof, or the material alloy thereof) or metal oxide conductive materials (e.g., indium tin oxide, indium zinc oxide, fluorine-doped indium oxide), metal nitride conductive materials (e.g., titanium nitride or molybdenum nitride), or a combination thereof. In some embodiments, the material of the conductive connection layer 140 includes a transparent conductive oxide.

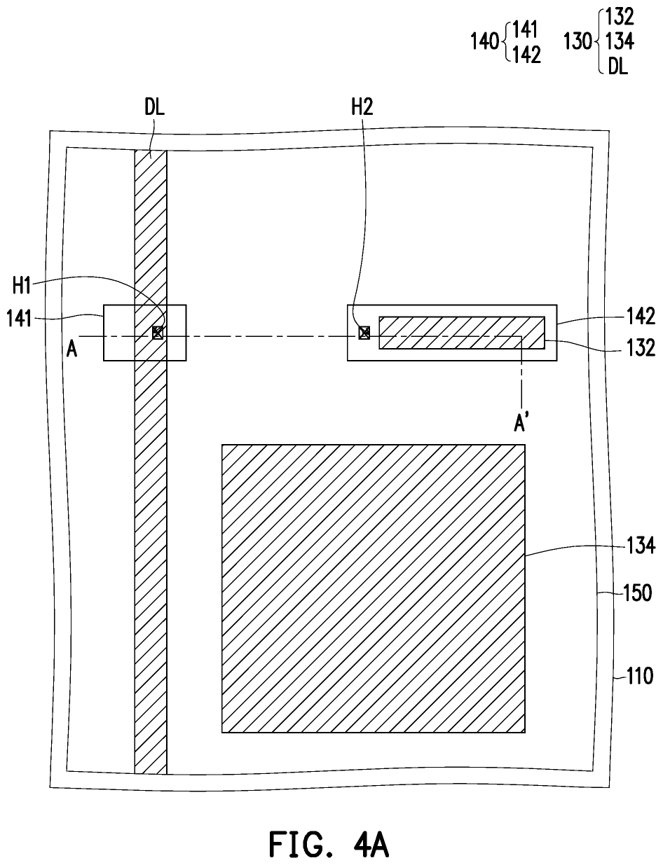

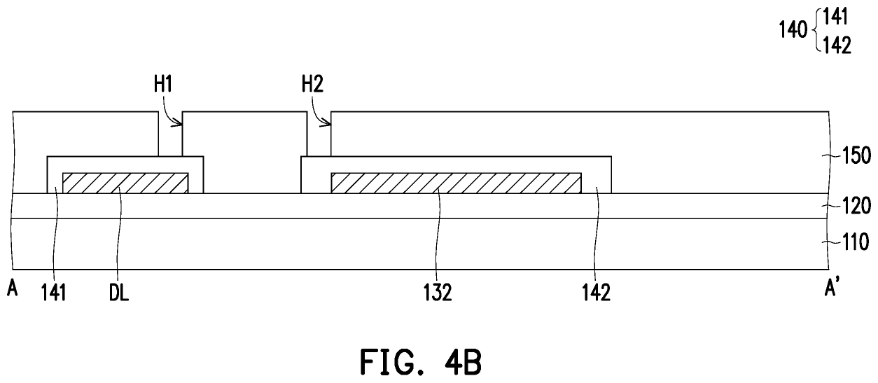

Referring to FIG. 4A and FIG. 4B, the planarization layer 150 is formed on the substrate 110; the planarization layer 150 covers the buffer layer 120, the first conductive layer 130, and the conductive connection layer 140; and the first opening H1 and the second opening H2 are formed in the planarization layer 150. The first opening H1 and the second opening H2 expose the first conductive connection pattern 141 and the second conductive connection pattern 142, respectively. The method for forming the first opening H1 and the second opening H2 includes a dry etching process using an oxidant. In this case, the first conductive connection pattern 141 and the second conductive connection pattern 142 can protect the first conductive layer 130 and prevent the first conductive layer 130 from being damaged by the dry etching process. The material of the planarization layer 150 may include various polymers, such as but not limited to polyvinylphenol, polyvinyl acetate, polyvinyl alcohol, polyacrylate, polymethacrylate, polymethylmethacrylate, polystyrene, polyvinylamine, polymaleimide, Polyimide, polyimide, silicone polymer, phenol formaldehyde (Novolac) resin, benzoxazole polymer, polyoxadiazole, maleic anhydride polymer, and copolymers thereof.

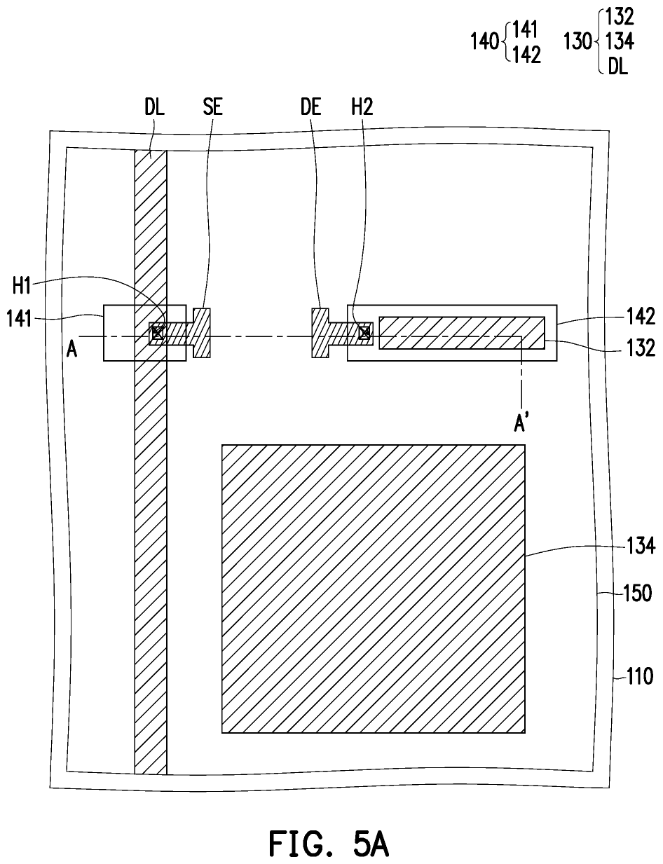

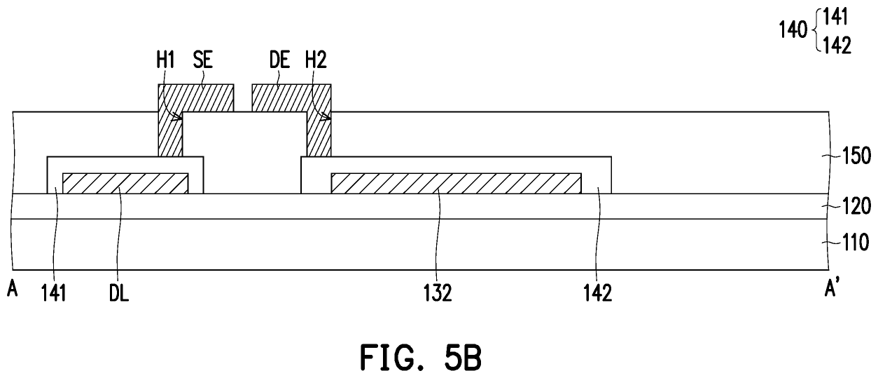

Referring to FIG. 5A and FIG. 5B, the source electrode SE is formed in the first opening H1, and the drain electrode DE is formed in the second opening H2, so the source electrode SE is electrically connected to the data line DL, and the drain electrode DE is electrically connected to the transfer wire 132. The source electrode SE and the drain electrode DE generally include metal materials, such as gold, silver, copper, aluminum, titanium, molybdenum, or a combination thereof, but the disclosure is not limited thereto. In other embodiments, the source electrode SE and the drain electrode DE may include alloys, nitrides of metallic materials, oxides of metallic materials, oxynitrides of metallic materials, other suitable materials, or stacked layers of the foregoing conductive materials. However, the disclosure is not limited thereto.

In some embodiments, the source electrode SE is connected to the data line DL through the first conductive connection pattern 141. In some embodiments, the source electrode SE is connected to the first conductive connection pattern 141 through the first opening H1 of the planarization layer 150. In some embodiments, the drain electrode DE is connected to the transfer wire 132 through the second conductive connection pattern 142. In some embodiments, the drain electrode DE is connected to the second conductive connection pattern 142 through the second opening H2 of the planarization layer 150.

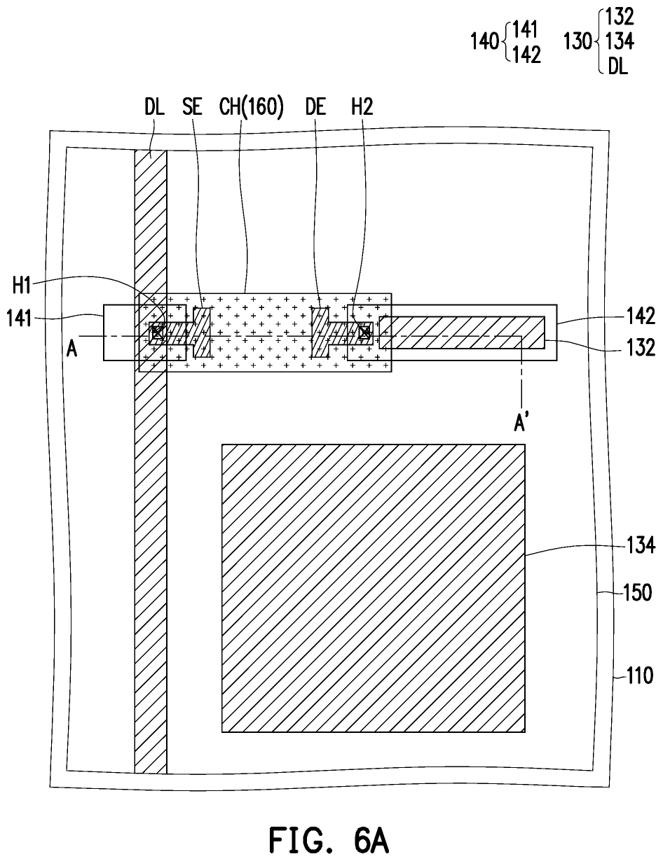

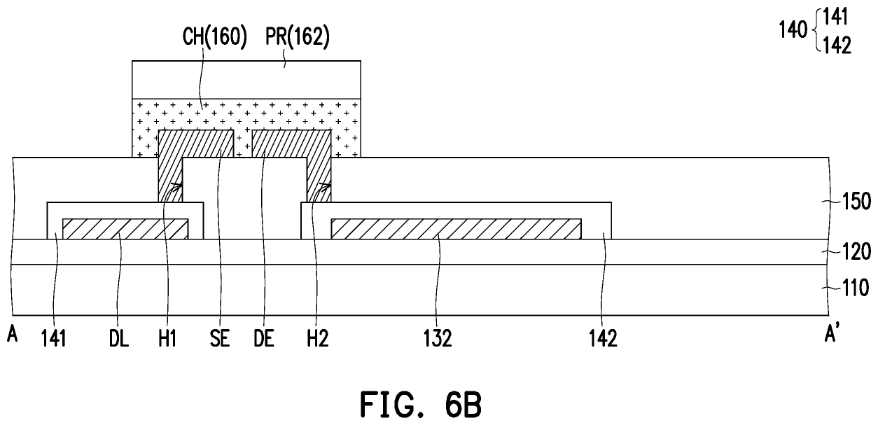

Referring to FIG. 6A and FIG. 6B, the organic semiconductor pattern CH is formed between the source electrode SE and the drain electrode DE. In some embodiments, an organic semiconductor layer 160 may be formed on the source electrode SE, the drain electrode DE, and the planarization layer 150 first. Then, a photoresist layer 162 may be formed on the organic semiconductor layer 160. Next, the photoresist layer 162 is patterned by a photolithography process to form the protection pattern PR, and the organic semiconductor layer 160 is etched with the protection pattern PR as a mask to form an organic semiconductor pattern CH, and the protection pattern PR is disposed on the upper surface of the organic semiconductor pattern CH. In some embodiments, the protection pattern PR may be further removed.

The material of the organic semiconductor layer 160 may include various fused heterocycles, aromatic hydrocarbons (e.g., pentacene), polythiophenes, fused (hetero)aromatic compounds (e.g., perylene imine and naphthalimide small molecules or polymers), random copolymers of polycyclic aromatic hydrocarbons (e.g., benzochalcogen, benzochalcogen, and triarylamine monomer units), polyacetylene, polyterephthalate and its derivatives, polyphthalate and its derivatives, polypyrrole and its derivatives, polythiophenol and its derivatives, polyfuran and its derivatives, polyaniline and its derivatives, other suitable materials, or a combination thereof.

In some embodiments, the organic semiconductor layer 160 includes at least one of the following compounds: 2,7-Dibromo[1]benzothieno[3,2-b][1]benzothiophene, 2,7-bis[(4,4,5,5-tetramethyl-1,3,2-dioxaborolan-2-yl)]-9,9-di-n-octylpyridine and 2-(4-(Diphenylamino)phenyl)-2-methylpropionitrile.

The material of the photoresist layer 162 may include an electrically insulating material, such as but not limited to fluoropolymer, polyisobutylene, poly(vinylphenol-co-methyl methacrylate), polyvinyl alcohol, polypropylene, polyvinyl chloride, polycyano pullulan, polyvinyl phenyl, polyvinyl cyclohexane, based on Benzocyclobutane polymer, polymethyl methacrylate, poly(styrene-co-butadiene), polycyclohexyl methacrylate, copolymer of methyl methacrylate and styrene, polymethoxystyrene (PMeOS), copolymer of methoxystyrene and styrene, polyacetoxystyrene (PAcOS), copolymer of acetoxystyrene and styrene, copolymer of styrene and vinyl toluene, polyvinylpyridine, polyvinyl fluoride, polyacrylonitrile, poly4-vinylpyridine, poly(2-ethyl-2-oxazoline), polytrimethylene Fluorochloroethylene, polyvinylpyrrolidone and polypentafluorostyrene.

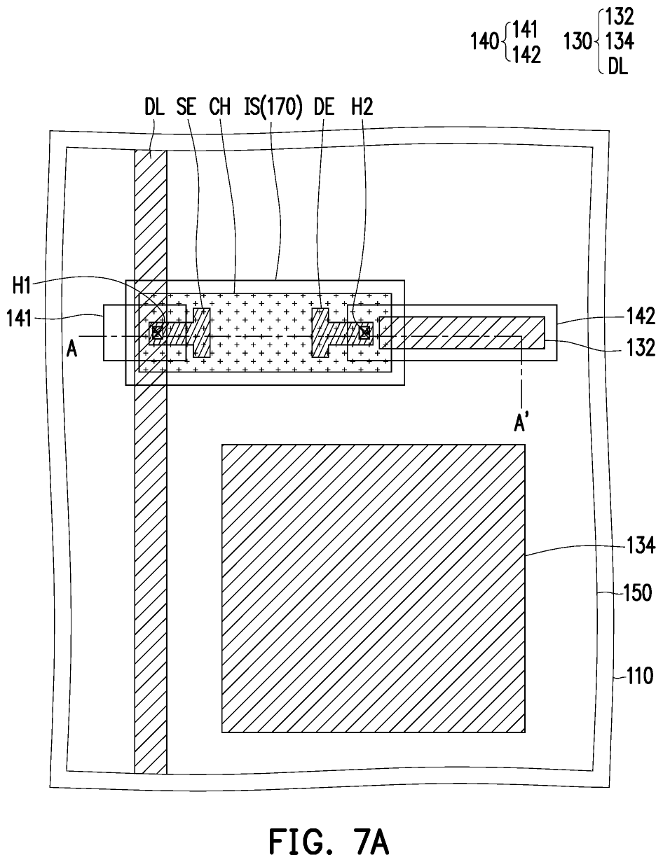

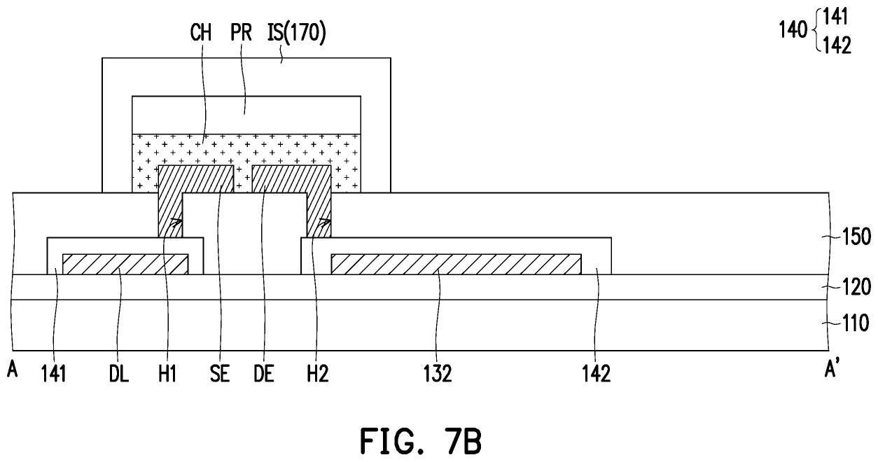

Referring to FIG. 7A and FIG. 7B, the organic insulating layer 170 is formed on the substrate 110 so that the protection pattern PR is sandwiched between the organic semiconductor pattern CH and the organic insulating layer 170. The organic insulating layer 170 may include an island-shaped portion IS, and the island-shaped portion IS covers the protection pattern PR and the organic semiconductor pattern CH. In some embodiments, the protection pattern PR is removed, and the island-shaped portion IS is disposed on the upper surface and the side surface of the organic semiconductor pattern CH and covers the organic semiconductor pattern CH.

The organic insulating layer 170 may have a single-layer or multi-layer structure, and the material of the organic insulating layer 170 may include electrical insulating materials, such as various dielectric polymers. The dielectric polymers may be a vinyl polymer obtained by polymerization of one or more acyclic vinyl monomers, polymers derived from one or more vinyl phenol monomers (e.g., poly-4-vinylphenol (PVP)), a copolymer of vinyl phenol, or a vinyl phenol derivative and at least one other vinyl monomer. Examples of the aforementioned acyclic vinyl monomers include ethylene, propylene, butadiene, styrene, vinyl phenol, vinyl chloride, vinyl acetate, acrylic esters (e.g., methacrylate, methyl methacrylate, acrylic acid, methacrylic acid, acrylamide), acrylonitrile and its derivatives. The vinyl monomers may be acrylic monomers, such as methyl methacrylate, methacrylate, acrylic acid, methacrylic acid, acrylamide or derivatives thereof.

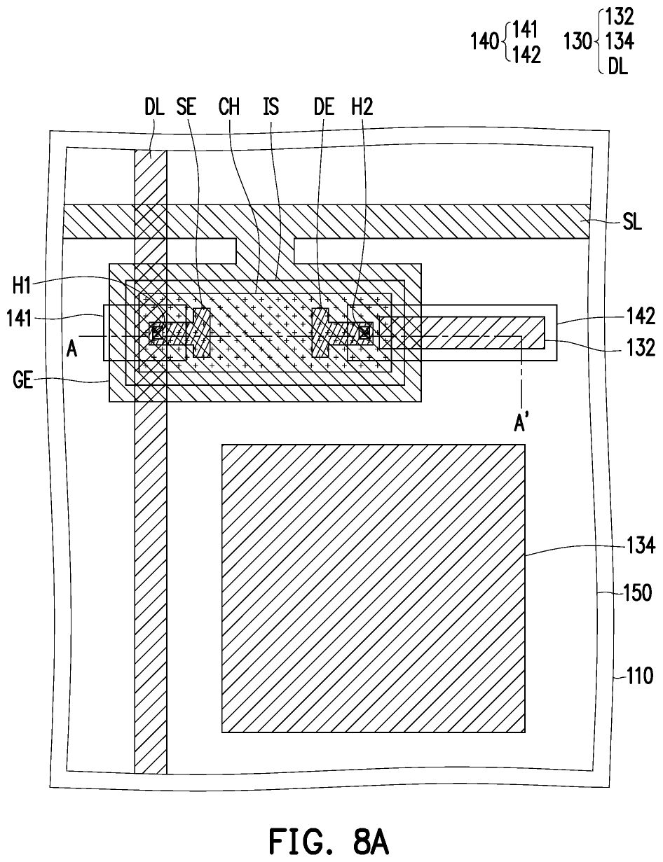

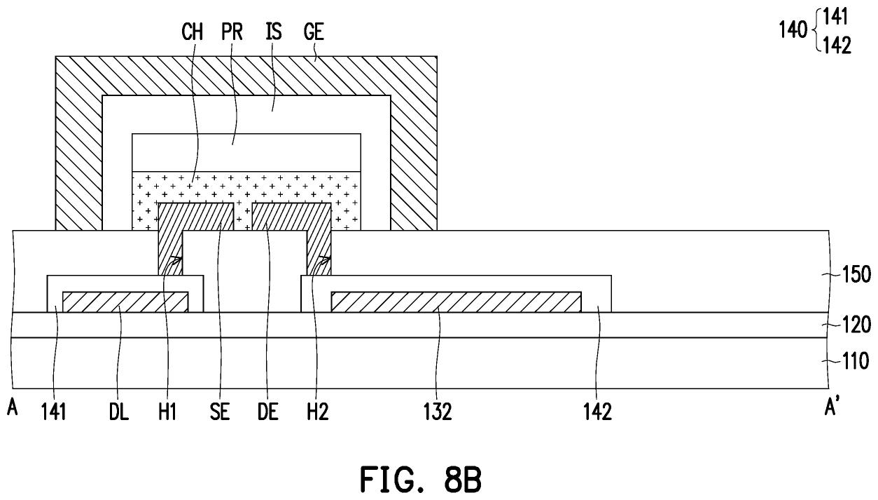

Referring to FIG. 8A and FIG. 8B, the gate electrode GE and the scan line SL are formed. The gate electrode GE is connected to the scan line SL, and the gate electrode GE covers the island-shaped portion IS of the organic insulating layer 170. With the gate electrode GE as a moisture blocking structure, moisture can be effectively prevented from entering the organic semiconductor device 10 and destroying the organic semiconductor pattern CH.

The gate electrode GE and the scan line SL may have a single-layer or multi-layer structure. Based on conductivity, the gate electrode GE and the scan line SL generally include metal materials, but the disclosure is not limited thereto. In other embodiments, for example, the materials of the gate electrode GE and the scan line SL are alloys, nitrides of metallic materials, oxides of metallic materials, oxynitrides of metallic materials, other suitable materials, or metallic materials and stacked layers of other conductive materials.

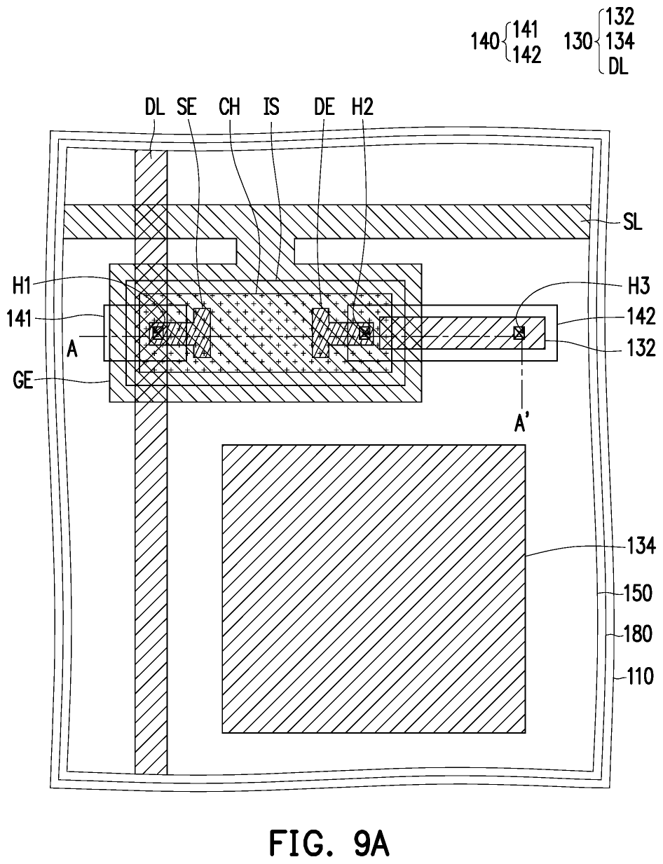

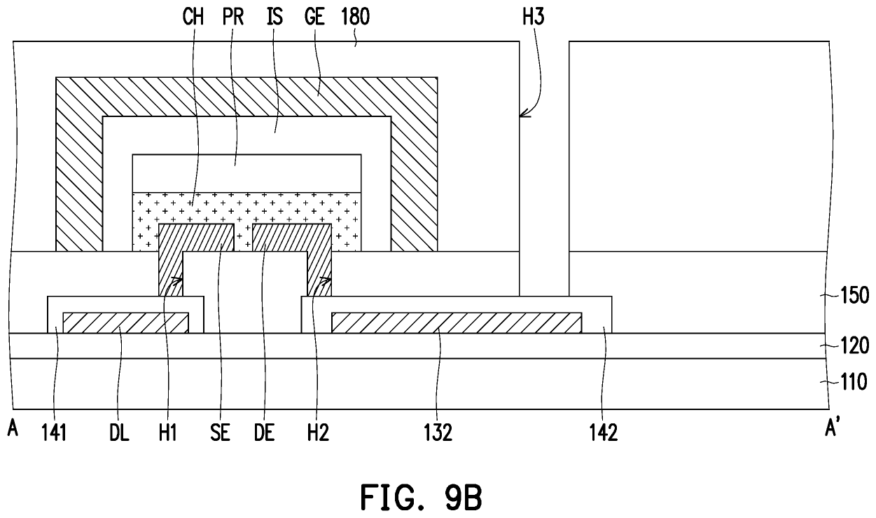

Referring to FIG. 9A and FIG. 9B, the organic protection layer 180 is formed on the substrate 110, and the third opening H3 is formed in the organic protection layer 180. The orthographic projection of the third opening H3 on the substrate 110 overlaps the orthographic projection of the second conductive connection pattern 142 on the substrate 110. The third opening H3 penetrates the organic protection layer 180 and the planarization layer 150 to expose the second conductive connection pattern 142. The method of forming the third opening H3 includes a dry etching process using an oxidant. During the etching, the second conductive connection pattern 142 can protect the transfer wire 132 from being damaged by the oxidant.

The material of the organic protection layer 180 may include a polymer having a hydroxyl side chain to react with a carboxylic acid containing (ethylene or) diene or a derivative thereof. For example, the organic protection layer 180 may include poly(2-hydroxyethyl methacrylate), poly(vinylphenol), poly(vinyl alcohol), and copolymers thereof, such as poly(vinyl alcohol-co-ethylene) or poly(vinyl alcohol). (Vinylphenol/methyl methacrylate), but the disclosure is not limited thereto.

The method of manufacturing the organic semiconductor device 10 according to an embodiment of the disclosure further includes a step of forming the pixel electrode PE on the upper surface of the organic protection layer 180 to complete the organic semiconductor device 10 as shown in FIG. 1A to FIG. 1B. In some embodiments, the orthographic projection of the pixel electrode PE on the substrate 110 at least partially overlaps the orthographic projection of the capacitor electrode 134 on the substrate 110, and the pixel electrode PE is electrically connected to the drain electrode DE through the third opening H3. In some embodiments, the pixel electrode PE is connected to the transfer wire 132 through the second conductive connection pattern 142. In some embodiments, the pixel electrode PE is connected to the second conductive connection pattern 142 through the third opening H3. The material of the pixel electrode PE may include a transparent conductive material, such as indium tin oxide, indium zinc oxide, aluminum tin oxide, aluminum zinc oxide, indium gallium zinc oxide, or a stacked layer of at least two thereof. In the embodiment, with the gate electrode GE as a moisture blocking structure, the organic semiconductor pattern CH of the organic semiconductor device 10 can be effectively protected from damages caused by moisture.

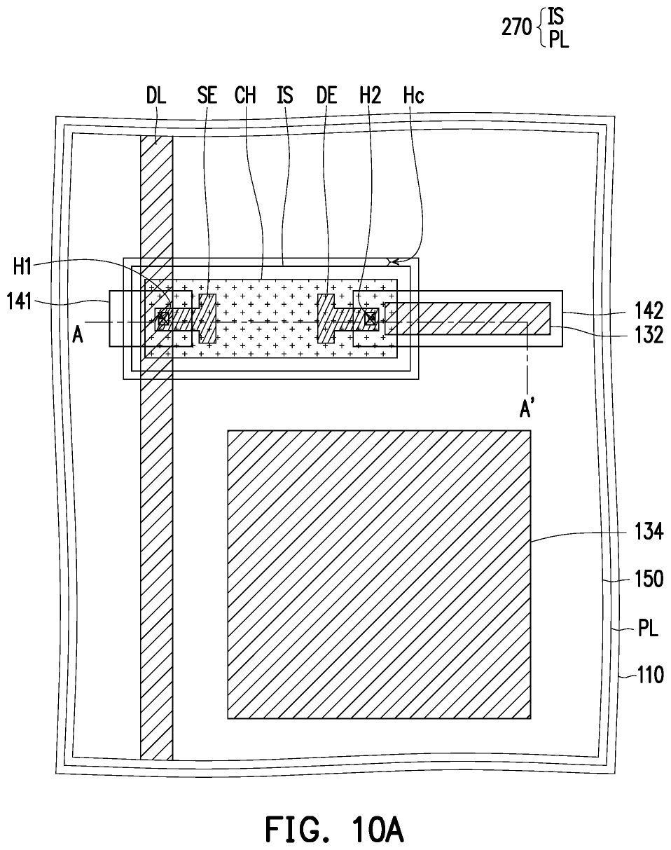

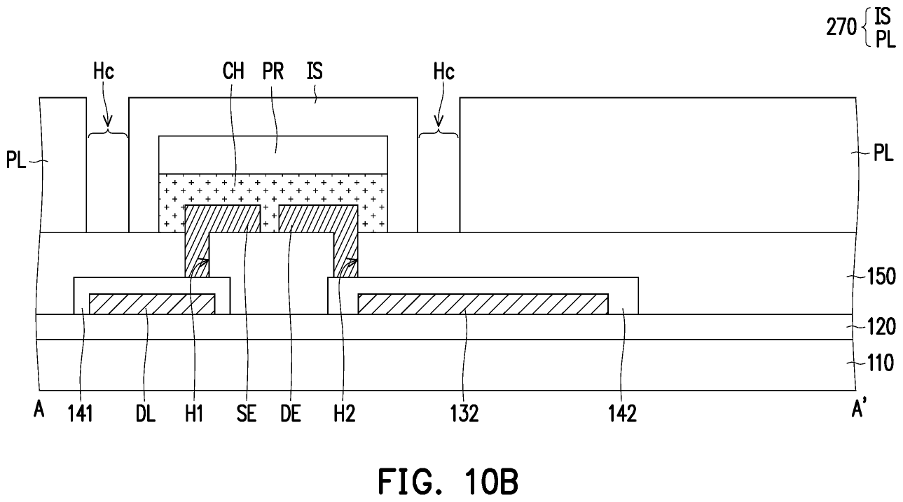

In the above embodiment, it is explained that the organic insulating layer 170 of the organic semiconductor device 10 includes the island-shaped portion IS. In the following embodiments, it is explained that an organic insulating layer 270 of an organic semiconductor device 20 includes the island-shaped portion IS and a planarization portion PL, and an annular space He sandwiched between the island-shaped portion IS and the planarization portion PL; and the method shown in FIG. 2A to FIG. 6B and FIG. 10A to FIG. 13B is adopted to realize the embodiments. The description of the same technical content as in FIG. 2A to FIG. 6B is omitted, and the same reference numerals are used in the description of the production steps in FIG. 10A to FIG. 13B to denote the same or similar elements. Regarding the description of the omitted parts, reference may be made to the embodiments of FIG. 2A to FIG. 6B, which is not iterated in the following description.

FIG. 10A to FIG. 13A are schematic top views of a method of manufacturing an organic semiconductor device 20 according to an embodiment of the disclosure. FIG. 10B to FIG. 13B are schematic cross-sectional views taken along the line A-A′ of FIG. 10A to FIG. 13A, respectively. In the subsequent paragraphs, with reference to FIG. 10A to FIG. 13A and FIG. 10B to FIG. 13B, the implementation of part of the elements and film layers of the organic semiconductor device 20 is illustrated, but the disclosure is not limited thereto.

Referring to FIG. 10A and FIG. 10B, after the organic semiconductor pattern CH and the protection pattern PR as shown in FIG. 6A to FIG. 6B are formed, the organic insulating layer 270 is formed on the substrate 110. The organic insulating layer 270 includes the island-shaped portion IS and the planarization portion PL. The island-shaped portion IS and the planarization portion PL have the annular space He sandwiched therebetween, and the annular space He surrounds the island-shaped portion IS. The island-shaped portion IS is disposed on the upper surface of the protection pattern PR and the side surfaces of the protection pattern PR and the organic semiconductor pattern CH, and the protection pattern PR is sandwiched between the island-shaped portion IS and the organic semiconductor pattern CH.

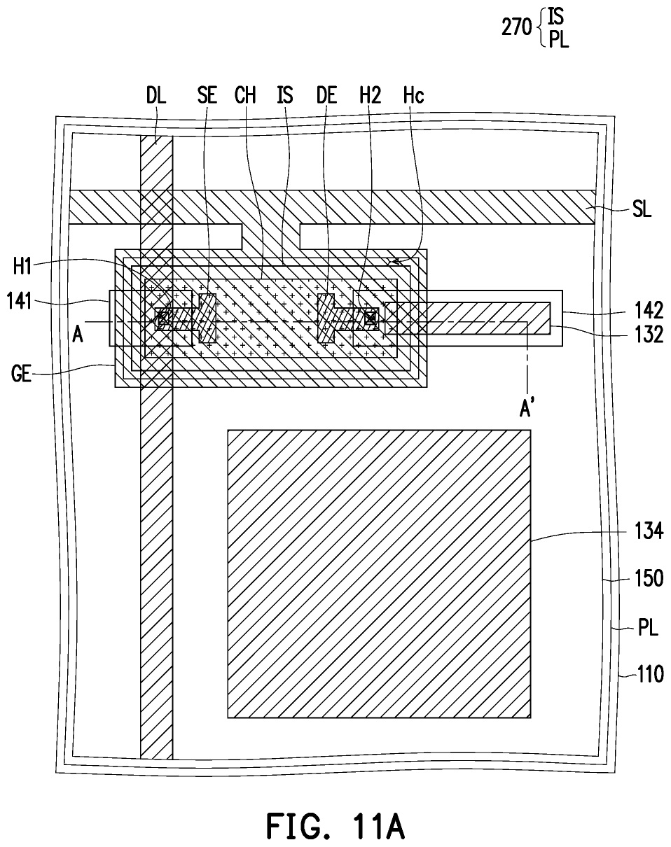

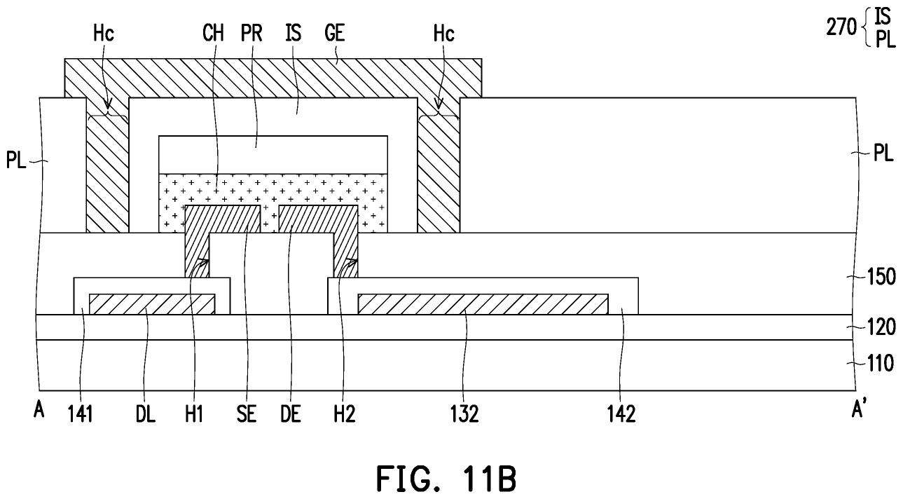

Referring to FIG. 11A and FIG. 11B, the gate electrode GE and the scan line SL are formed. The gate electrode GE is connected to the scan line SL. In some embodiments, the gate electrode GE is filled in the annular space Hc, and the gate electrode GE surrounds the island-shaped portion IS. The island-shaped portion IS of the organic insulating layer 270 is disposed at least between the side surface of the organic semiconductor pattern CH and the gate electrode GE and between the upper surface of the organic semiconductor pattern CH and the gate electrode GE. In some embodiments, the gate electrode GE is filled in the annular space He and covers the island-shaped portion IS, but the annular space He is not completely filled. With the gate electrode GE as a moisture blocking structure, the organic semiconductor pattern CH can be effectively protected from damages caused by moisture.

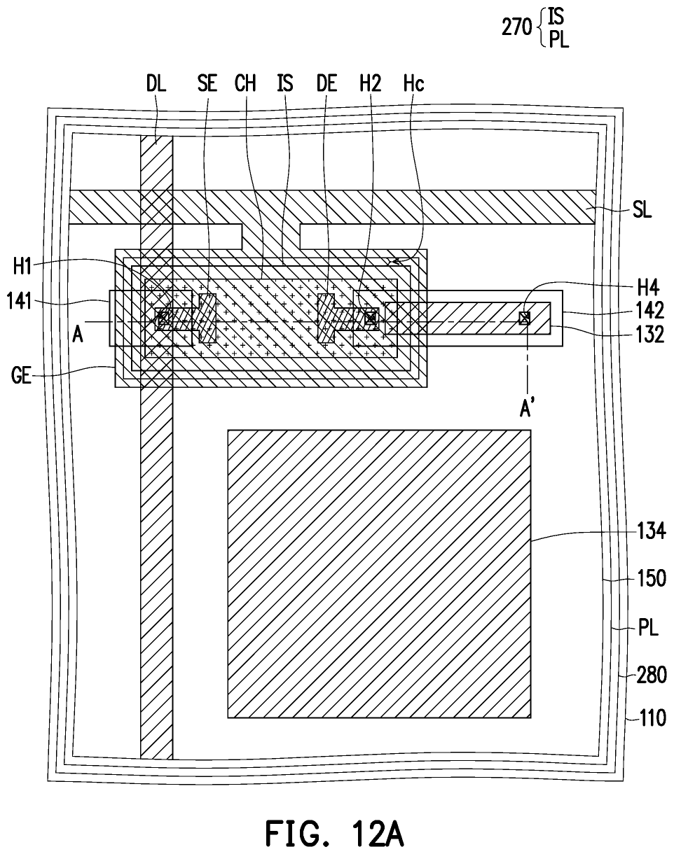

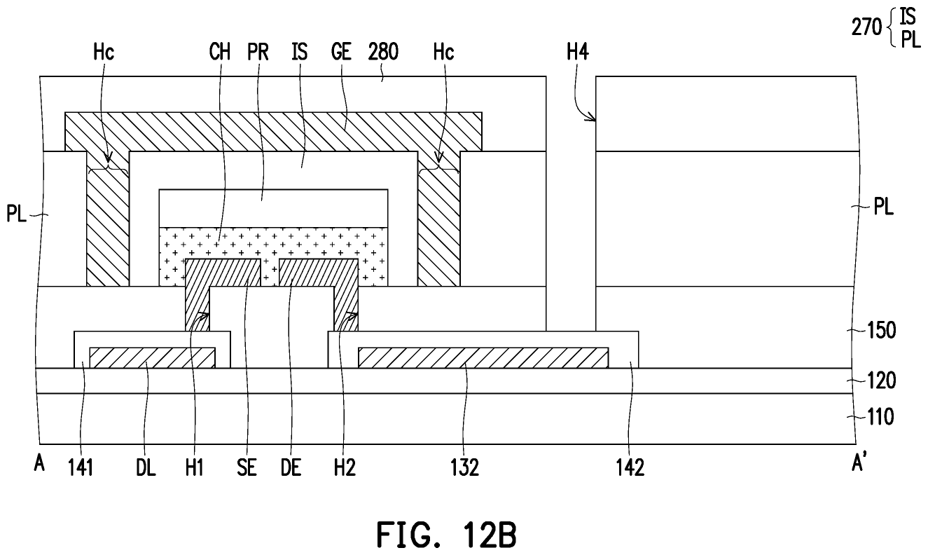

Referring to FIG. 12A and FIG. 12B, an organic protection layer 280 is formed on the substrate 110, and a fourth opening H4 is formed in the organic protection layer 280. The fourth opening H4 penetrates the organic protection layer 280, the organic insulating layer 270, and the planarization layer 150 and exposes the second conductive connection pattern 142. In some embodiments, the organic protection layer 280 is disposed on the gate electrode GE and the upper surface of the organic insulating layer 270 to cover the gate electrode GE. In some embodiments, the organic protection layer 280 is filled in the annular space He and between the planarization portion PL and the gate electrode GE.

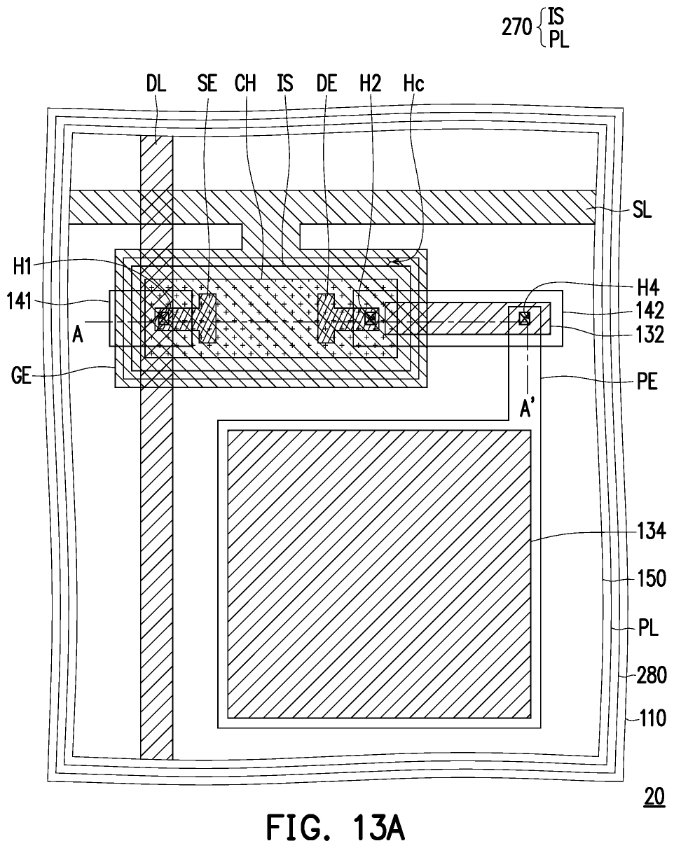

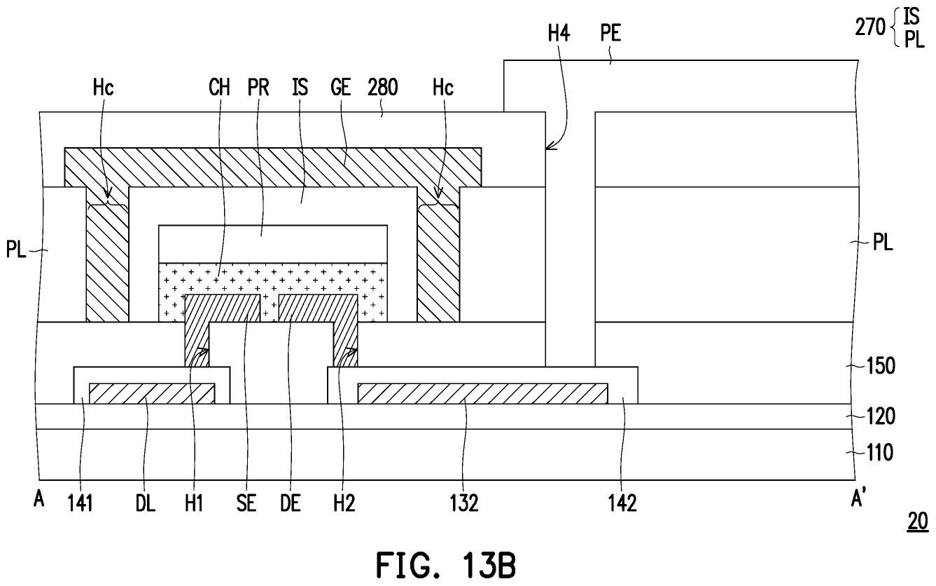

Referring to FIG. 13A and FIG. 13B, the pixel electrode PE is formed on the upper surface of the organic protection layer 280 to form the organic semiconductor device 20. In some embodiments, the orthographic projection of the pixel electrode PE on the substrate 110 at least partially overlaps the orthographic projection of the capacitor electrode 134 on the substrate 110. In some embodiments, the orthographic projection of the capacitor electrode 134 on the substrate 110 completely falls within the orthographic projection of the pixel electrode PE on the substrate 110. In some embodiments, the pixel electrode PE is electrically connected to the drain electrode DE through the fourth opening H4. In some embodiments, the pixel electrode PE is connected to the transfer wire 132 through the second conductive connection pattern 142. In some embodiments, the pixel electrode PE is connected to the second conductive connection pattern 142 through the fourth opening H4. The pixel electrode PE can be electrically connected to the drain electrode DE through the second conductive connection pattern 142 and the transfer wire 132. The pixel electrode PE and the capacitor electrode 134 together constitute the storage capacitor of the organic semiconductor device 20.

In the organic semiconductor device 20, with the gate electrode GE and the organic protection layer 280 as a moisture blocking structure, the organic semiconductor pattern CH of the organic semiconductor device 20 is effectively protected from damages caused by moisture.

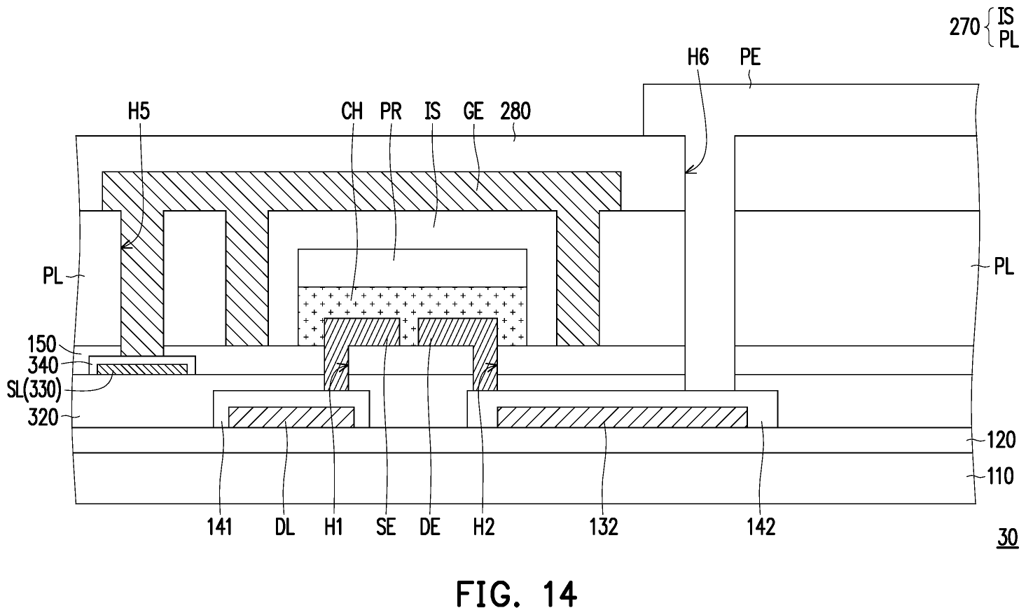

FIG. 14 is a schematic cross-sectional view of an organic semiconductor device 30 according to an embodiment of the disclosure. Compared to the structure of the organic semiconductor device 20 shown in FIG. 13B, the structure of the organic semiconductor device 30 shown in FIG. 14 is different because an interlayer insulating layer 320, a second conductive layer 330, and a third conductive connection pattern 340 are further disposed between the planarization layer 150 and the conductive connection layer 140. The interlayer insulating layer 320 is sandwiched between the conductive connection layer 140 and the first conductive layer 130 and the second conductive layer 330, the second conductive layer 330 is sandwiched between the interlayer insulating layer 320 and the third conductive connection pattern 340, the third conductive connection pattern 340 is sandwiched between the second conductive layer 330 and the planarization layer 150, and the second conductive layer 330 includes the scan line SL. In some embodiments, the gate electrode GE is electrically connected to the scan line SL through the third conductive connection pattern 340. In some embodiments, the gate electrode GE is connected to the third conductive connection pattern 340 through a fifth opening H5 penetrating the planarization portion PL and the planarization layer 150. In some embodiments, the material of the third conductive connection pattern 340 includes transparent conductive oxide.

Moreover, the pixel electrode PE may be connected to the second conductive connection pattern 142 through a sixth opening H6 penetrating the organic protection layer 280, the planarization portion PL, the planarization layer 150, and the interlayer insulating layer 320. Therefore, the pixel electrode PE can be electrically connected to the drain electrode DE through the second conductive connection pattern 142 and the transfer wire 132. The pixel electrode PE and the capacitor electrode 134 together constitute the storage capacitor of the organic semiconductor device 30.

Based on the above, the organic semiconductor device of the disclosure blocks moisture through the gate electrodes disposed on the upper surface and the side surface of the organic semiconductor pattern, so as to protect the organic semiconductor pattern. Moreover, the organic material/inorganic material stack of the organic protection layer and the gate electrode also contributes to blocking moisture and preventing the properties of the organic semiconductor pattern from being affected by moisture, which can improve the yield of the organic semiconductor device.

Although the disclosure has been described with reference to the above embodiments, they are not intended to limit the disclosure. It will be apparent to one of ordinary skill in the art that modifications and changes to the described embodiments may be made without departing from the spirit and the scope of the disclosure. Accordingly, the scope of the disclosure will be defined by the attached claims and their equivalents and not by the above detailed descriptions.

What is claimed is:

1. An organic semiconductor device, comprising:
a substrate;
a scan line disposed on the substrate;
a data line disposed on the substrate;
a source electrode and a drain electrode disposed on the substrate, wherein the source electrode is electrically connected to the data line;
an organic semiconductor pattern disposed on the substrate and between the source electrode and the drain electrode;
an organic insulating layer disposed on the substrate and on an upper surface and a side surface of the organic semiconductor pattern;
a gate electrode disposed on the substrate, wherein the organic insulating layer is disposed at least between the side surface of the organic semiconductor pattern and the gate electrode and between the upper surface of the organic semiconductor pattern and the gate electrode, and the gate electrode is electrically connected to the scan line; and
an organic protection layer disposed on the substrate and covering the gate electrode.

2. The organic semiconductor device according to claim 1, wherein the organic semiconductor pattern surrounds the source electrode and the drain electrode.

3. The organic semiconductor device according to claim 1, wherein the organic insulating layer comprises an island-shaped portion and a planarization portion, an annular space is sandwiched between the island-shaped portion and the planarization portion, and the annular space surrounds the island-shaped portion.

4. The organic semiconductor device according to claim 3, wherein the gate electrode is filled in the annular space.

5. The organic semiconductor device according to claim 1, wherein the organic insulating layer comprises an island-shaped portion, and the gate electrode covers the island-shaped portion.

6. The organic semiconductor device according to claim 1, further comprising a protection pattern, wherein the protection pattern is disposed on the upper surface of the organic semiconductor pattern and sandwiched between the organic semiconductor pattern and the organic insulating layer.

7. The organic semiconductor device according to claim 1, further comprising a planarization layer, wherein the planarization layer is disposed between the source electrode and the drain electrode and the substrate, and at least one of the scan line and the data line is disposed between the planarization layer and the substrate.

8. The organic semiconductor device according to claim 7, further comprising a conductive connection pattern, wherein the source electrode is connected to the data line through the conductive connection pattern.

9. The organic semiconductor device according to claim 8, wherein the source electrode is connected to the conductive connection pattern through an opening of the planarization layer.

10. The organic semiconductor device according to claim 7, further comprising a conductive connection pattern, wherein the gate electrode is connected to the scan line through the conductive connection pattern.

11. The organic semiconductor device according to claim 10, wherein the gate electrode is connected to the conductive connection pattern through an opening of the planarization layer.

12. The organic semiconductor device according to claim 1, further comprising a buffer layer, wherein the buffer layer is disposed between the scan line and the data line and the substrate.

13. The organic semiconductor device according to claim 1, further comprising a pixel electrode, wherein the pixel electrode is disposed on an upper surface of the organic protection layer and is electrically connected to the drain electrode.
